(19) United States
(12) Patent Application Publication
(10) Pub. No.: US 2011/0083727 A1
(43) Pub. Date: Apr. 14, 2011

(54) PHOTOELECTRODE FOR DYE SENSITIZED SOLAR CELL, METHOD OF MANUFACTURING THE SAME, AND DYE SENSITIZED SOLAR CELL USING THE SAME

(76) Inventors: Byong-Cheol Shin, Yongin-si (KR); Ji-Won Lee, Yongin-si (KR); Moon-Sung Kang, Yongin-si (KR); Ji-Man Kim, Yongin-si (KR); Sung-Soo Kim, Yongin-si (KR)

(21) Appl. No.: 12/838,410

(22) Filed: Jul. 16, 2010

(30) Foreign Application Priority Data
Oct. 13, 2009 (KR) 10-2009-0097447

(51) Int. Cl. H01L 31/042; H01L 31/18

(52) U.S. Cl. 136/254; 427/74; 216/24

(57) ABSTRACT

A photoelectrode for a dye sensitized solar cell, a method of preparing the same, and a dye sensitized solar cell using the photoelectrode. The photoelectrode includes mesoporous titanium dioxide particles with an average particle diameter in a range of about 100 to about 2000 nm and a specific surface area in a range of about 150 to about 300 m²/g, wherein the mesopores of the mesoporous titanium dioxide particles have an average pore diameter in a range of about 2 to about 7 nm.

### CROSS-REFERENCE TO RELATED APPLICATION

This application claims priority to and the benefit of Korean Patent Application No. 10-2009-0097447, filed on Oct. 13, 2009, in the Korean Intellectual Property Office, the entire content of which is incorporated herein by reference.

### BACKGROUND

1. Field

One or more embodiments of the present invention relate to a photoelectrode for a dye sensitized solar cell, a method of manufacturing the same, and a dye sensitized solar cell using the photoelectrode.

2. Description of the Related Art

A dye sensitized solar cell may include a photoelectrode to which a photosensitive dye is adsorbed, an electrolyte containing oxidation/reduction ion pairs, and a counter electrode including a platinum (Pt) catalyst. The photoelectrode may include metal oxide particles having a wide band gap.

In dye sensitized solar cells, if solar light is incident to the solar cell, a photosensitive dye absorbs light, is excited into an excitation state and transfers electrons into a conduction band of a metal oxide. The conducted electrons flow to an external circuit to transfer electric energy thereto, and then flow to a counter electrode.

Then, the photosensitive dye receives, from an electrolyte, an equal number of electrons as those emitted to the metal oxide, and returns to the ground state. In this regard, the electrolyte transfers electrons from the counter electrode to the photosensitive dye through oxidation and reduction.

Energy conversion efficiency may be increased if the loss of solar light received by the photosensitive dye of the dye sensitized solar cell is reduced. Energy conversion efficiency may also be increased if the charge generated from the photosensitive dye by solar light is smoothly transferred to each electrode.

### SUMMARY

An aspect of one or more embodiments of the present invention is directed toward a photoelectrode for a dye sensitized solar cell having high efficiency, a method of manufacturing the same, and a dye sensitized solar cell using the photoelectrode.

Additional aspects will be set forth in part in the description which follows and, in part, will be apparent from the description, or may be learned by practice of the presented embodiments.

According to one or more embodiments of the present invention, a photoelectrode for a dye sensitized solar cell includes: mesoporous titanium dioxide particles having an average particle diameter in a range of about 100 to about 2000 nm and a specific surface area in a range of about 150 to about 300 m²/g; and a photosensitive dye on a surface of the titanium dioxide particles.

The mesopores of the mesoporous titanium dioxide particles may have a distance between the mesopores in a range of about 4 to about 15 nm. Mesopores of the mesoporous titanium dioxide particles may have an average pore diameter in a range of about 2 to about 7 nm and a pore volume in a range of about 0.03 to about 0.08 cc/g.

The mesoporous titanium dioxide particles may exhibit at least one main diffraction peak at least one Bragg (20) angle in a range of about 0.8 to about 1.2 degrees, about 1.5 to about 3 degrees, or about 25 to about 30 degrees when CuK-alpha x-rays having a wavelength of 1.541 Å are irradiated thereto.

According to one or more embodiments of the present invention, a method of manufacturing a photoelectrode for a dye sensitized solar cell includes: preparing a composition for a photoelectrode by mixing mesoporous titanium dioxide particles, a polymer binder, an acid, and a solvent; coating the composition for a photoelectrode on a substrate; and heat treating the coated composition.

The mesoporous titanium dioxide particles may be prepared by: preparing a titanium dioxide precursor mixture by mixing a titanium dioxide precursor, an acid, and a solvent; impregnating mesoporous silica with the titanium dioxide precursor mixture and drying and heat treating the resultant; and removing the mesoporous silica from the heat-treated resultant.

According to one or more embodiments of the present invention, a dye sensitized solar cell includes: a first electrode; a photoelectrode according to any of the above located on one surface of the first electrode; a second electrode facing the first electrode on which the photoelectrode is located; and an electrolyte between the first electrode and the second electrode.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 schematically shows formation of mesoporous titanium dioxide according to an embodiment of the present invention.

FIG. 2 is a cross-sectional view of a dye sensitized solar cell according to an embodiment of the present invention.

FIG. 3 is an electron microscopic image of mesoporous titanium dioxide prepared according to Preparation Example 1.

FIG. 4 shows X-ray diffraction (XRD) test results for mesoporous titanium dioxide prepared according to Preparation Example 1.

FIG. 5 is a graph illustrating pore distribution for mesoporous titanium dioxide prepared according to Preparation Example 1.

FIG. 6 is a graph illustrating an I-V curve for a dye sensitized solar cell prepared according to Example 1.

FIG. 7 is a graph illustrating UV-visible spectra for dyes adsorbed to photoelectrodes of dye sensitized solar cells prepared according to Example 1 and Comparative Examples 1 and 2.

FIG. 8 is a graph illustrating incident-photon-to-current efficiency (IPCE) for dye sensitized solar cells prepared according to Example 1 and Comparative Examples 1 and 2.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when a first element is referred to as being “on” a second element, it can be directly on the second element or be indirectly on the second element with one or more intervening elements interposed therebetween. Like reference numerals designate like elements throughout the specification.

A photoelectrode for a dye sensitized solar cell, according to an embodiment of the present invention, includes mesoporous titanium dioxide particles and a photosensitive dye on the surface thereof. The mesoporous titanium dioxide particles have an average particle diameter in a range of about 100 to 500 nm, a specific surface area in a range of about 150 to about 300 m²/g, wherein the mesopores of the mesoporous titanium dioxide particles have an average pore diameter in a range of about 2 to about 7 nm.

A distance between the pores of the mesoporous titanium dioxide particles is in the range of about 4 to about 15 nm. The mesopores have a pore volume in a range of about 0.03 to about 0.08 cc/g. In this regard, the distance between the pores indicates an interval (or a gap) between the pores.

The mesoporous titanium dioxide particles have a cylindrical or spherical shape and exhibit at least one main diffraction peak at least one Bragg (20) angle in a range of about 0.8 to about 1.2 degrees, about 1.5 to about 3 degrees, or about 25 to about 30 degrees when CuK-alpha x-rays having a wavelength of 1.541 Å are irradiated thereto. For example, the mesoporous titanium dioxide particles exhibit main diffraction peaks at a Bragg (2θ) angle in a range of about 0.8 to about 1.2 degrees, about 1.5 to about 3 degrees, or about 25 to about 30 degrees when CuK-alpha x-rays having a wavelength of 1.541 Å are irradiated thereto. Without being so limited, such diffraction peaks may be regarded as characteristics of ordered mesoporous titanium dioxide. The X-ray diffraction characteristics are analyzed using CuK-α radiation by a D/MAX-III (Rigaku) instrument at a Bragg (2θ) angle in a range of about 0.8 to about 80 degrees.

A method of manufacturing mesoporous titanium dioxide according to an embodiment of the present invention will now be described.

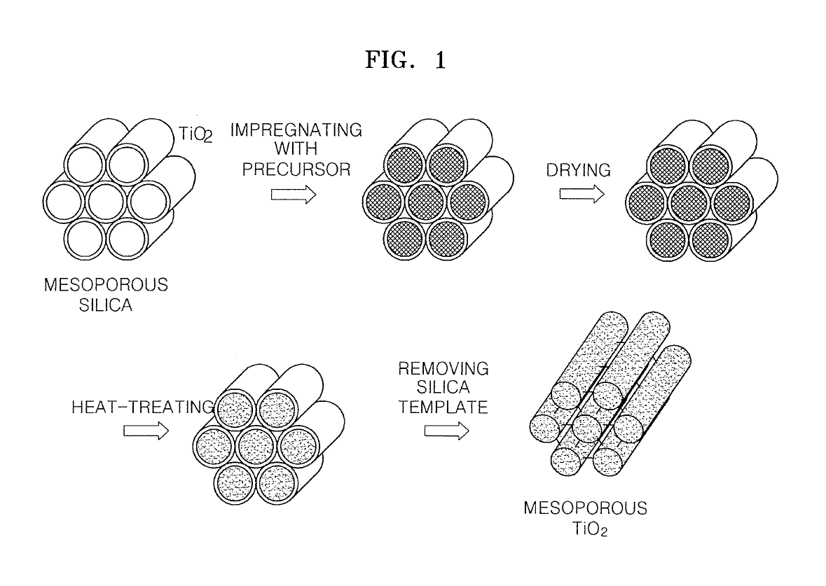

FIG. 1 schematically shows formation of mesoporous titanium dioxide according to an embodiment of the present invention.

First, a titanium dioxide (TiO₂) precursor is introduced into an ordered mesoporous silica (OMS) template, and the resultant is dried and heat-treated to form an OMS-carbon complex. In this regard, the OMS is a mesoporous silica having regular alignment of pores so that XRD diffraction peaks are observed at a Bragg (2θ) angle of 2 degrees or less when CuK-alpha x-rays having a wavelength of 1.541 Å are irradiated thereto.

Then, the OMS is removed from the OMS-carbon complex to obtain mesoporous titanium dioxide, for example, ordered mesoporous titanium dioxide.

Hereinafter, a method of manufacturing the mesoporous titanium dioxide, according to an embodiment of the present invention, will be described in more detail.

A titanium dioxide precursor mixture is prepared by mixing a titanium dioxide precursor, an acid, and a solvent.

The mesoporous silica is impregnated with the prepared titanium dioxide precursor mixture, and the resultant is dried and heat-treated.

The titanium dioxide precursor may be titanium chloride and/or titanium alkoxide such as titanium ethoxide, titanium methoxide, and/or titanium isopropoxide.

The acid may be an organic and/or inorganic acid. For example, the acid may be sulfuric acid, nitric acid, phosphoric acid, and/or p-toluene sulfuric acid.

The amount of the titanium dioxide precursor may be in the range of about 50 to about 120 parts by weight based on 100 parts by weight of the mesoporous silica. If the amount of the titanium dioxide precursor is within the range described above, the mesoporous titanium dioxide may be ordered without agglomeration.

Any solvent that may uniformly disperse the titanium dioxide precursor may be used as the solvent. Examples of the solvent are water, acetone, methanol, ethanol, isopropyl alcohol, n-propyl alcohol, butanol, dimethylacetamide, dimethylformamide, dimethyl sulfoxide, N-methyl-2-pyrrolidone, tetrahydrofurane, tetrabutylacetate, n-butylacetate, m-cresol, toluene, ethylene glycol, γ-butyrolactone, and hexafluoro-isopropanol (HFIP). These solvents may be used alone or in combination.

The amount of the acid in the titanium dioxide precursor mixture may be in the range of about 30 to about 500 parts by weight based on 100 parts by weight of the mesoporous silica. If the amount of the acid is within the range described above, the mesoporous titanium dioxide may be efficiently formed. The amount of the solvent in the titanium dioxide precursor mixture may be in the range of about 200 to about 900 parts by weight based on 100 parts by weight of the mesoporous silica. If the amount of the solvent is within the range described above, the titanium dioxide precursor may be dissolved in the solvent without agglomeration of particles.

The mesoporous silica may be any molecular sieve material having one-dimensional pores connected to each other via micropores, or the like without limitation. Non-limiting examples of the mesoporous silica are cubic MCM-48 as a molecular sieve material having a three-dimensionally connected structure, SBA-1 with another cubic structure, SBA-15 having a hexagonal structure, KIT-1 having MSU-1 pores irregularly and three-dimensionally connected to each other, and various suitable molecular sieve materials including various suitable mesoporous molecular sieve materials having one-dimensional pores.

The impregnation may be performed at room temperature, but is not limited thereto.

In addition, the mesoporous silica may be commercially available or prepared according to the following method.

First, a surfactant is dissolved in distilled water to a set or predetermined concentration. Then, a silica precursor is added thereto, and the mixture is stirred.

The silica precursor may be, for example, colloidal silica (Ludox HS-40 (Aldrich)), or the like.

The size and shape of the mesopores may vary according to the type and concentration of the surfactant, and the shape of the particles may vary according to the stirring time, and stirring temperature. The surfactant may be, for example, poly(ethylene glycol)-block-poly(propylene glycol)-block-poly(ethylene glycol) (P123(M.W.5750)).

The amount of the surfactant may be in the range of about 5 to about 30 parts by weight based on 100 parts by weight of the silica precursor.

After the reaction is terminated, the resultant is filtered, dried, and heat-treated to remove the remaining surfactant, thereby obtaining mesoporous silica.

The heat treatment may be performed at a temperature in a range of about 400 to about 550° C.

After the impregnation process, the mixture is dried. In this regard, the drying temperature may be in the range of about 80 to about 160° C., but the drying temperature is not limited thereto. The drying may be performed under a reduced pressure to reduce the drying time.

The dried resultant as described above may be heat treated, or the process described above may be repeated 2 to 10 times. That is, the dried resultant may be impregnated with the prepared titanium dioxide precursor mixture. Then, the drying process is performed in the same manner as described above.

As described above, after the drying process, a heat-treatment process is performed.

The heat-treatment process may be performed using a heating unit such as an electric furnace at a temperature in a range of about 400 to about 550° C. If the heat-treatment process is performed within the temperature range described above, the pores of the mesoporous titanium dioxide may be uniformly maintained.

The heat-treatment process may be performed in a non-oxidizing atmosphere such as a vacuum atmosphere, a nitrogen atmosphere, or an inert gas atmosphere.

Then, the mesoporous silica template is removed from the resultant by using a solvent that may selectively dissolve the mesoporous silica template.

The solvent that may selectively dissolve the mesoporous silica includes a sodium hydroxide (NaOH) solution. In this regard, the concentration of the sodium hydroxide (NaOH) solution may be in the range of about 5 to about 30 wt %.

The mesoporous titanium dioxide prepared according to an embodiment of the present invention is an ordered mesoporous titanium oxide in which pores are regularly arranged.

In addition, the mesoporous titanium dioxide has mesopores having an average pore diameter in a range of about 2 to about 7 nm and a specific surface area in a range of about 150 to about 300 m²/g.

Since the mesoporous titanium dioxide has mesopores regularly arranged, main diffraction peaks are observed at least one Bragg (2θ) angle in a range of about 0.8 to about 1.2 degrees, about 1.5 to about 3 degrees, or about 25 to about 30 degrees when CuK-alpha x-rays having a wavelength of 1.541 Å are irradiated thereto.

Without being limited by theory, the main diffraction peak observed at a Bragg (2θ) angle in a range of about 0.8 to about 1.2 degrees may be caused by a regular arrangement of mesopores, and the main diffraction peak observed at a Bragg (2θ) angle in a range of about 25 to about 30 degrees may be caused by a regular arrangement of titanium and oxygen in a titanium oxide backbone.

As described above, the mesoporous titanium dioxide is used to prepare a photoelectrode for a dye sensitized solar cell.

A method of manufacturing the photoelectrode for a dye sensitized solar cell and a dye sensitized solar cell including the photoelectrode, according to embodiments of the present invention, will be described below.

A composition for a photoelectrode is prepared by mixing mesoporous titanium dioxide particles, a polymer binder, an acid, and a solvent.

The composition is in a paste form with a viscosity in a range of about 10000 to about 30000 mPas (vis 30). The acid may be hydrochloric acid, nitric acid, acetic acid, or the like, and the amount of the acid may be in the range of about 50 to about 500 parts by weight based on 100 parts by weight of the mesoporous titanium dioxide.

The polymer binder may be ethylcellulose, hydropropylcellulose, or the like, and the amount of the polymer binder may be in the range of about 1 to about 50 parts by weight based on 100 parts by weight of the mesoporous titanium dioxide.

The solvent may be terpineol, ethanol, distilled water, ethylene glycol, α-terpineol, or the like, and the amount of the solvent may be in the range of about 200 to about 900 parts by weight based on 100 parts by weight of the mesoporous titanium dioxide. In this regard, if the amount of the solvent is within the range described above, the photoelectrode may have excellent photo current characteristics.

The composition for the photoelectrode is coated on a first electrode located on a first substrate and heat treated at a temperature in a range of about 400 to about 550° C. to form a photoelectrode.

The composition for the photoelectrode may be coated on the first electrode by spin coating, dip coating, casting, or the like, and the thickness of the photoelectrode may be in the range of about 10 to about 3000 nm.

A photosensitive dye is adsorbed to a surface of the photoelectrode.

The photosensitive dye may be ruthenium-based dye, N3, N719, black dye, or the like. In this regard, N3 is RuL₂ (NCS)₂ (L=2,2′-bipyridyl-4,4′-dicarboxylic acid), and N719 is [RuL₂(NCS)₂](TBA)₂ (L=2,2′-bipyridyl-4,4′-dicarboxylic acid, TBA=tetra-n-butylammonium).

The titanium dioxide membrane is dipped in a solution including 3 to 7 mM photosensitive dye to adsorb the photosensitive dye to the titanium dioxide membrane.

In this regard, ethanol, isopropanol, acetonitrile, and/or valeronitrile are used as the solvent.

Then, the photoelectrode to which the photosensitive dye is adsorbed is combined with a second substrate on which a second electrode is located so as to face the first electrode, and an electrolyte is injected between the first electrode and the second electrode to manufacture a dye sensitized solar cell.

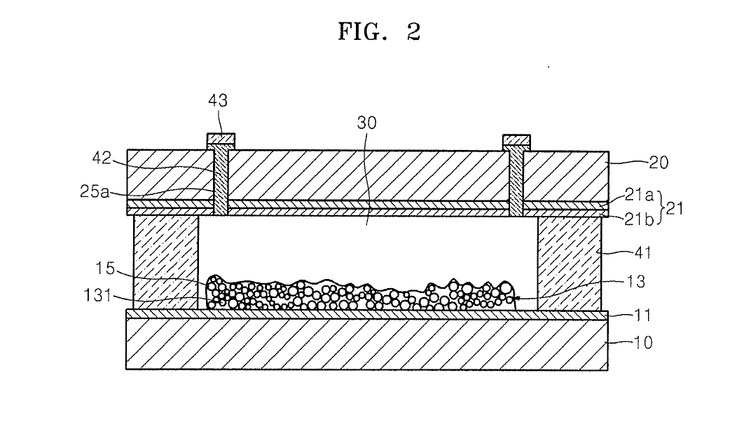

FIG. 2 is a cross-sectional view of a dye sensitized solar cell according to an embodiment of the present invention.

Referring to FIG. 2, the dye sensitized solar cell according to the current embodiment of the present invention includes a first substrate 10 on which a first electrode 11, a photoelectrode 13 and a dye 15 are located; a second substrate 20 on which a second electrode 21 is located; and an electrolyte 30 located between the first electrode 11 and the second electrode 21, wherein the first substrate 10 and the second substrate 20 face each other. A case may be provided to contain or house the first substrate 10 and the second substrate 20. The structure will be described in more detail below.

The first substrate 10 which supports the first electrode 11 is transparent and thus light can be transmitted therethrough. In this regard, the first substrate 10 may be formed of glass and/or plastic. Examples of the plastic include polyethylene terephthalate (PET), polyethylene naphthalate (PEN), polycarbonate (PC), polypropylene (PP), polyimide (PI), and triacetyl cellulose (TAC).

The first electrode 11 located on the first substrate 10 may be formed of a transparent material selected from an indium tin oxide, an indium oxide, a tin oxide, a zinc oxide, a sulfur oxide, a fluorine oxide, a mixture thereof, ZnO—Ga₂O₃, and/or ZnO—Al₂O₃. The first electrode 11 may have a single or multi-layer structure including the transparent material.

The photoelectrode 13 is located on the first electrode 11. The photoelectrode 13 includes a plurality of mesoporous titanium dioxide particles 131. A suitable average pore size may improve transfer of the electrolyte 30, and may thereby improve necking characteristics of the mesoporous titanium dioxide particles 131.

The thickness of the photoelectrode 13 may be in the range of about 10 nm to about 3000 nm, for example, from about 10 nm to about 1000 nm. However, the thickness of the photoelectrode 13 is not limited thereto.

The dye 15 which absorbs light and generates exited electrons is adsorbed to a surface of the photoelectrode 13.

In one embodiment, the dye 15 is an organic dye that has a suitable molar extinction coefficient and suitable photoelectric efficiency in a visible light wavelength range, is relatively inexpensive, and can be used as a replacement for expensive inorganic ruthenium dye.

Also, the second substrate 20 which supports the second electrode 21 and is located to face the first substrate 10 may be transparent. The second substrate 20, like the first substrate 10, may also be formed of glass and/or plastic.

The second electrode 21 located on the second substrate 20 is located to face the first electrode 11, and may include a transparent electrode 21a and a catalyst electrode 21b.

The transparent electrode 21a may be formed of a transparent material such as an indium tin oxide, a fluoro tin oxide, an antimony tin oxide, a zinc oxide, a tin oxide, ZnO—Ga₂O₃, ZnO—Al₂O₃, or the like. In this regard, the transparent electrode 21a may have a single or multi-layer structure including the transparent material. The catalyst electrode 21b activates a redox couple, and may be formed of platinum (Pt), ruthenium (Ru), palladium (Pd), iridium (Ir), rhodium (Rh), osmium (Os), carbon (C), WO₃, TiO₂, or the like.

The first substrate 10 is combined with the second substrate 20 using an adhesive 41. The electrolyte 30 is injected into the space between the first electrode 11 and the second electrode 21 through a hole 25a penetrating the second substrate 20 and the second electrode 21. The electrolyte 30 is uniformly dispersed in the photoelectrode 13. The electrolyte 30 transfers electrons from the second electrode 21 to the dye 15 through oxidation and reduction. The hole 25a penetrating the second substrate 20 and the second electrode 21 is sealed using an adhesive 42 and a cover glass 43.

A porous metal oxide membrane may further be formed on the upper surface of the first electrode 11 and the lower surface of the photoelectrode 13. In this regard, the photoelectrode 13 may function as a light scattering electrode and adsorb a large amount of the dye 15, thereby increasing efficiency of the dye sensitized solar cell.

The porous metal oxide membrane may be formed of metal oxide particles including a titanium oxide, a zinc oxide, a tin oxide, a strontium oxide, an indium oxide, an iridium oxide, a lanthanum oxide, a vanadium oxide, a molybdenum oxide, a tungsten oxide, a niobium oxide, a magnesium oxide, an aluminum oxide, a yttrium oxide, a scandium oxide, a samarium oxide, a gallium oxide, a strontium titanium oxide, or the like. In this regard, the metal oxide particles may be formed of TiO₂, SnO₂, WO₃, ZnO, or a complex thereof.

Since light scattering of the photoelectrode 13 is induced according to the particle diameter of the mesoporous titanium dioxide, and photocurrent density is increased by the mesopores adsorbing a large amount of the dye 15, a dye sensitized solar cell including the photoelectrode 13 has high efficiency.

Hereinafter, one or more embodiments of the present invention will be described in more detail with reference to the following examples. However, these examples are not intended to limit the purpose and scope of the present invention.

### Preparation Example 1

### Synthesis of Mesoporous Titanium Dioxide

### 1) Synthesis of Ordered Mesoporous Silica (OMS) (MSU-H Synthesis Method Used in Example 1)

The molar ratio of SiO₂:NaOH:P123:CH₃COOH:H₂O in the mixture was 1:2.41:0.017:2.5:258.

A silica solution was prepared using Ludox HS-40 (Aldrich), NaOH, and H₂O such that the amount of SiO₂ was 10 wt % and the ratio of Na/Si was 2.5.

Separately, 16.408 g of P123 was dissolved in 615.6 g of H₂O at room temperature, and 100 g of the silica solution was added thereto, and then the mixture was stirred for 10 minutes. Then, 26.1 g of acetic acid (CH₃COOH, 99.8%) was mixed with 100 g of water to prepare a mixture of SiO₂:NaOH:P123:CH₃COOH:H₂O. The mixture was stirred in a reaction chamber for 10 minutes. Then, the reaction chamber was stirred in a thermostat at 318 K for 24 hours and aged in an oven at 373 K.

After the reaction, the resultant was filtered to obtain mesoporous silica, and the mesoporous silica was gradually dried at room temperature to obtain a white powder sample. 1 g of the white powder sample, 2.5 g of HCl (35 wt %), and 100 g of ethanol were stirred in a reaction chamber for 2 hours in order to wash the white powder sample. The resultant was filtered, dried in an oven at 353 K, and calcined in an oxygen atmosphere at 823 K to produce mesoporous silica MSU-H 1.

### 2) Preparation of Mesoporous Titanium Dioxide

3 g of titanium ethoxide was added to 30 ml of H₂O, and the mixture was stirred for 30 minutes and centrifuged at 4000 rpm to obtain a white precipitate.

The supernatant was carefully decanted and then removed, and 5.49 g of HCl was added thereto. Then, the mixture was stirred for 20 minutes to dissolve the white precipitate. The resultant was stored at a temperature of 273 K in a cooling room for 1 hour.

0.8 ml of a TiO₂ precursor solution was added to 1 g of the MSU-H using a micro pipette and were mixed so that the TiO₂ precursor solution was impregnated in the pores of the MSU-H. Then, the resultant was dried in an oven at 433 K for 10 minutes. This process was repeated 5 to 15 times. Then, the impregnated resultant was held in an oven at 373 K for 24 hours and heated to 673 K over a time period of 5 hours and maintained at 673 K for 3 hours.

After the heat treatment was terminated, the mixture of the silica and TiO₂ was added to 250 g of 1 M NaOH, and the mixture was heated to 373 K while stirring.

The mixture was maintained at 373K for 5 minutes, cooled at room temperature, and filtered. As such, the filtered powder was added to a desiccator and moisture was removed therefrom in a vacuum.

The mesoporous titanium dioxide obtained according to the process described above had a specific surface area of about 153 m²/g, a distance between pores of about 1 nm, and a pore volume of about 0.04 cc/g.

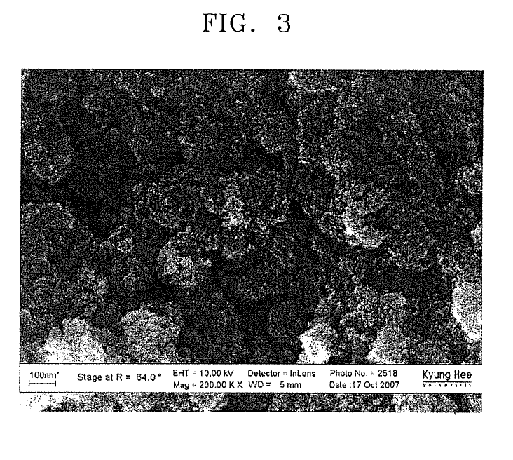

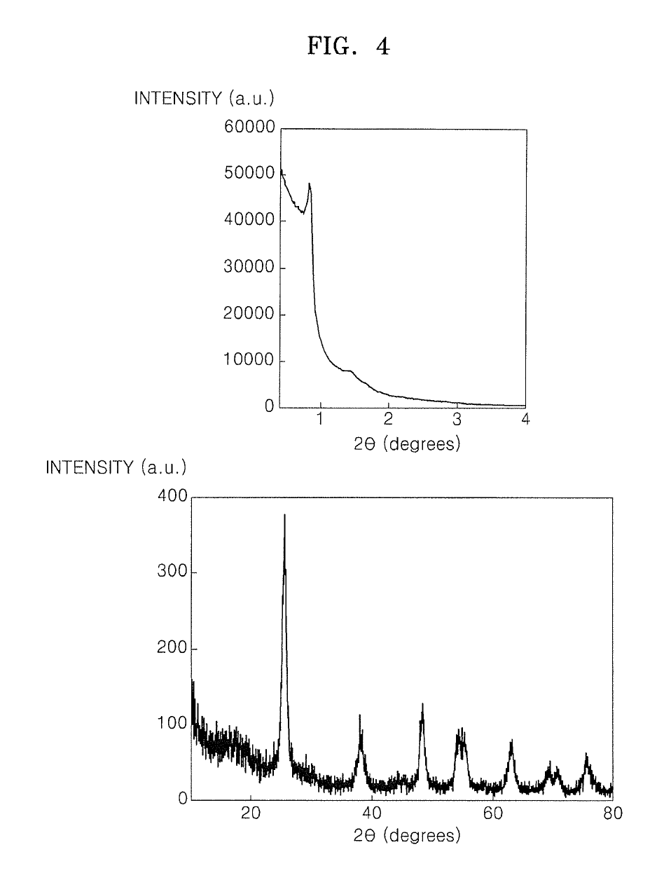

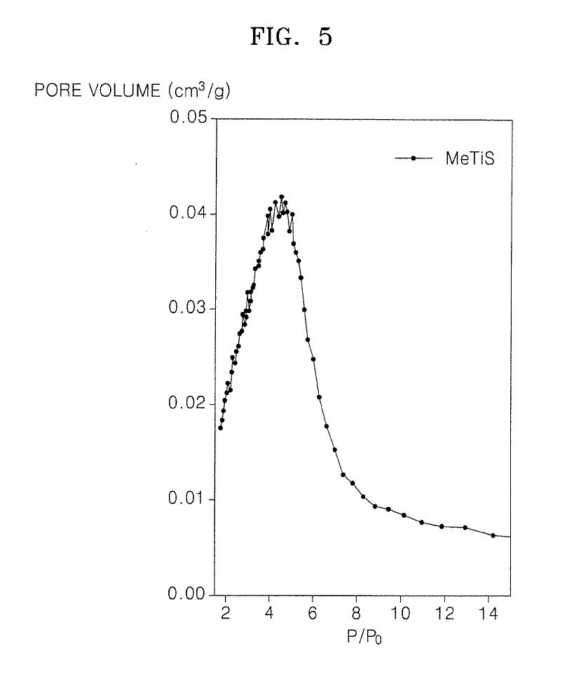

FIG. 3 is an electron microscopic image of mesoporous titanium dioxide prepared according to Preparation Example 1. FIG. 4 shows X-ray diffraction (XRD) test results of mesoporous titanium dioxide prepared according to Preparation Example 1. FIG. 5 is a graph illustrating pore distribution of mesoporous titanium dioxide prepared according to Preparation Example 1.

Referring to FIG. 3, an average particle diameter of the mesoporous titanium dioxide particles is about 150 nm.

Referring to FIG. 4, the mesoporous titanium dioxide is in the form of anatase. That is, the crystalline form of the titanium dioxide is anatase. Referring to FIG. 5, an average diameter of the mesopores of the mesoporous titanium dioxide is about 5 nm.

### Example 1

### Manufacture of Dye-Sensitized Solar Cell

A first photoelectrode having a thickness in a range of about 7 to about 8 μm was prepared using a titanium dioxide paste manufactured by CClC (Japan) and disposed on an ITO conductive film. In the titanium dioxide paste of CClC, titanium dioxide particles having a diameter of about 15 nm were mixed with α-terpineol, as a solvent, and other additives to produce 15 to 20 wt % titanium dioxide particles.

A second photoelectrode was formed on the first photoelectrode to a thickness of about 4 to about 5 μm by coating a paste for a photoelectrode including 15 parts by weight of spherical mesoporous titanium dioxide prepared according to Preparation Example 1, 0.5 parts by weight of hydropropylcellulose as a polymer binder, 50 parts by weight of nitric acid, and 32 parts by weight of distilled water as a solvent on the first photoelectrode, drying the coating, and heat treating the resultant at 500° C. for 30 minutes.

Then, the resultant was maintained at 80° C. and immersed in a dye dispersion prepared by dispersing N719 as a dye in ethanol to a concentration of 0.3 mM for 12 hours or more for adsorbing the dye to the resultant, thereby forming a dye-adsorbed porous membrane.

Then, the dye-adsorbed porous membrane was washed with ethanol and dried at room temperature.

Separately, a second electrode, as a counter electrode, was prepared by preparing a glass substrate coated with FTO, masking an area of 1.5 cm² of a conductive surface of the substrate using an adhesive tape, coating a H₂PtCl₆ solution on the substrate using a spin coater, and heat treating the resultant at 500° C. for 30 minutes.

Acetonitrile electrolyte including 0.5 M Lil and 0.05 M I was injected into the space between the first electrode and the second electrode to prepare a dye sensitized solar cell.

### Comparative Example 1

### Preparation of Dye Sensitized Solar Cell Using Spherical Titanium Dioxide Particles Having a Diameter of 400 nm

A first photoelectrode having a thickness in a range of about 7 to about 8 μm was prepared using a titanium dioxide paste manufactured by CClC (Japan) and formed on a first electrode formed of an ITO conductive film. In the titanium dioxide paste of CClC, titanium dioxide particles having a diameter of about 15 nm were mixed with α-terpineol, as a solvent, and other additives to be from 15 to 20 wt %.

A second photoelectrode was formed on the first photoelectrode to a thickness of about 4 to about 5 μm by coating a paste for a photoelectrode including 15 to 20 weight % of nanoporous titanium dioxide particles having an average diameter of 400 nm and α-terpineol as a solvent on the first electrode, drying the coated paste, and heat treating the resultant at 500° C. for 30 minutes.

Then, the resultant was maintained at 80 t and immersed in a dye dispersion prepared by dispersing N719 as a dye in ethanol to a concentration of 0.3 mM for 12 hours or more for adsorbing the dye to the resultant, thereby forming a dye-adsorbed porous membrane.

Then, the dye-adsorbed porous membrane was washed with ethanol and dried at room temperature.

Separately, a second electrode was prepared by depositing a second conductive film formed by sputtering Pt on a first conductive film formed of ITO. A hole for injecting an electrolyte was formed using a drill having a diameter of 0.75 mm.

A support having a thickness of 60 μm and formed of a thermoplastic polymer film (Surlyn, DuPont, USA) was disposed between the first electrode and the second electrode, and the resultant was pressed at 100° C. for 9 seconds to combine the first and second electrodes. Then, the electrolyte prepared according to Preparation Example 1 was injected through the hole formed in the second electrode, and then the hole was sealed using a cover glass and a thermoplastic polymer film, thereby completing the manufacture of a dye sensitized solar cell.

### Comparative Example 2

### Preparation of Dye Sensitized Solar Cell Including Single Layered Electrode Using TiO₂ Nanoparticles

A first photoelectrode having a thickness in a range of about 7 to about 8 μm was prepared using a titanium dioxide paste manufactured by CClC (Japan) and was formed on a first electrode formed of an ITO conductive film. The titanium dioxide paste of CClC includes titanium dioxide particles having a diameter of about 15 nm and with α-terpineol, as a solvent, and additives. Here the amount of the titanium dioxide particles was included to be from 15 to 20 wt %.

The resultant was maintained at 80° C. and immersed in a dye dispersion prepared by dispersing N719 as a dye in ethanol to a concentration of 0.3 mM for 12 hours or more for adsorbing the dye to the resultant, thereby forming a dye-adsorbed porous membrane.

Then, the dye-adsorbed porous membrane was washed with ethanol and dried at room temperature.

Separately, a second electrode was prepared by depositing a second conductive film formed by sputtering Pt on a first conductive film. A hole was formed in the second electrode for injecting an electrolyte by using a drill having a diameter of 0.75 mm.

A support having a thickness of 60 μm and formed of a thermoplastic polymer film (Surlyn, DuPont, USA) was located between the first electrode and the second electrode, and the resultant was pressed at 100° C. for 9 seconds to combine the first and second electrodes. Then, the electrolyte prepared according to Preparation Example 1 was injected through the hole formed in the second electrode, and then the hole was sealed using a cover glass and a thermoplastic polymer film, thereby completing the manufacture of a dye sensitized solar cell.

According to Comparative Example 1, a second photoelectrode formed of titanium dioxide particles having an average diameter of 400 nm was formed on the first photoelectrode. According to Comparative Example 2, the first photoelectrode did not have a second photoelectrode formed thereon.

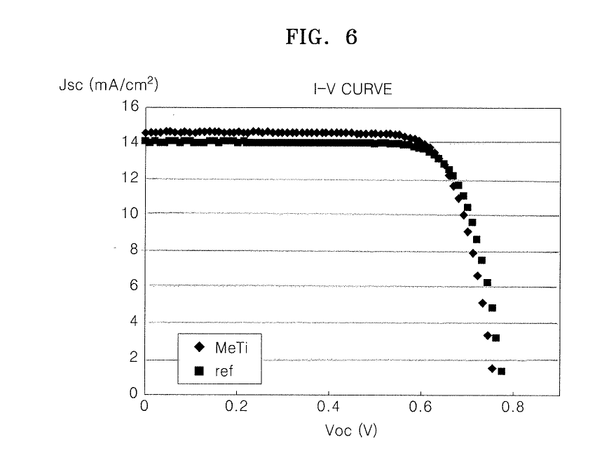

Current-voltage characteristics of the dye sensitized solar cells prepared according to Example 1 and Comparative Example 1 were measured at 1 sun light intensity and AM 1.5 conditions and in a dark condition, and the results are shown in FIG. 6. In FIG. 6, MeTi shows the results obtained in Example 1, and ref shows the results obtained in Comparative Example 1. Here, the “1 sun” refers to the intensity of a light source corresponding to that of the sun, and the “AM 1.5” refers to a filter adjusting wavelength to that of sunlight.

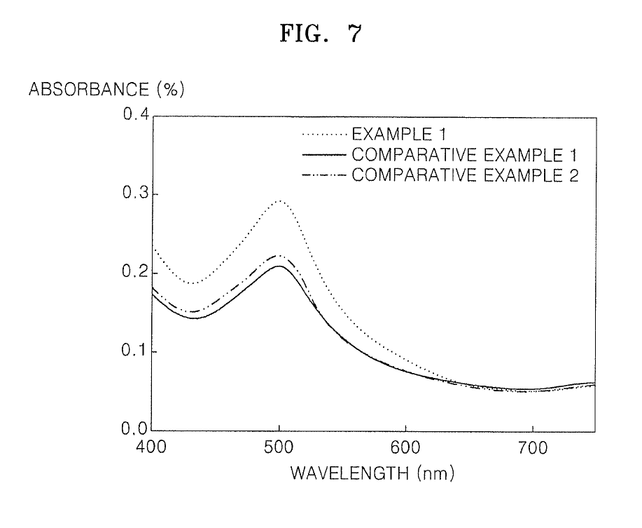

Referring to FIG. 6, it was identified that the dye sensitized solar cell prepared according to Example 1 had higher photocurrent density than the dye sensitized solar cell prepared according to Comparative Example 1. The results are shown in Table 1. The increase in the photocurrent density is caused by the high amount of dye adsorbed (see FIG. 7).

FIG. 7 is a graph illustrating UV-visible spectra of dyes adsorbed to photoelectrodes of dye sensitized solar cells prepared according to Example 1 and Comparative Examples 1 and 2. In FIG. 7, “Example 1” shows the results obtained in Example 1, “Comparative Example 2” shows the results obtained in Comparative Example 2, and “Comparative Example 1” shows the results obtained in Comparative Example 1.

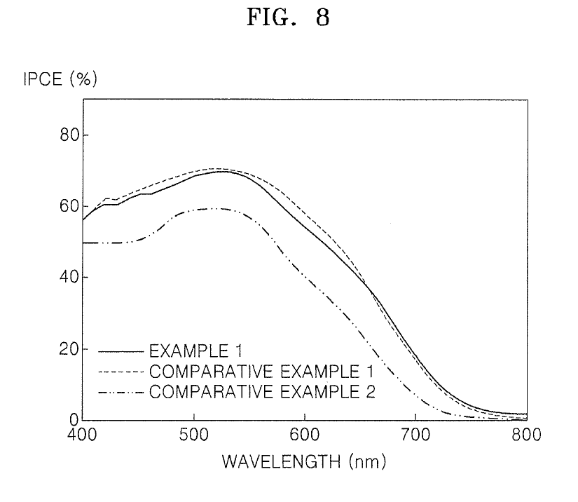

FIG. 8 is a graph illustrating incident-photon-to-current efficiency (IPCE) of dye sensitized solar cells prepared according to Example 1 and Comparative Examples 1 and 2.

Referring to FIGS. 7 and 8, electrodes using mesoporous titanium dioxide particles had light scattering effects as shown by the incident-photon-to-current efficiency (IPCE, FIG. 8). Current density was increased by the adsorbed dye scattering effects. Such effects were observed for wavelengths in a range of about 500 to about 650 nm as shown in FIG. 8.

Referring to FIG. 8, the electrode of the dye sensitized solar cell prepared according to Example 1 which uses titanium dioxide particles showed greater light scattering effects compared to the dye sensitized solar cells prepared according to Comparative Examples 1 and 2. Without being limited by theory, the formation of the paste of mesoporous particles improved the photocurrent density by increasing the adsorption of the dye and improved the IPCE by increasing scattering effects.

Photocurrent density of the dye sensitized solar cells prepared according to Example 1 and Comparative Examples 1 and 2 were measured, and open circuit voltage, current density, and fill factor were calculated from the photocurrent curve. The results are shown in Table 1 below, and efficiencies of the dye sensitized solar cells were evaluated. In this regard, a xenon (Xe) lamp was used as the light source, and the sun condition of the xenon lamp was adjusted using Fraunhofer Institute Solare Engeriessysysteme, Certificate No C-ISE369, Type of material, Mono-Si+KG filter, and the photo current density was measured at a power density of 100 mW/cm².

The conditions for measuring the open circuit voltage, photocurrent density, energy conversion efficiency, fill factor, and the amount of dye adsorbed shown in Table 1 below were as follows.

(1) Open circuit voltage (V) and photocurrent density (mA/cm²):

Open circuit voltage (V) and photocurrent density (mA/cm²) were measured using a Keithley SMU2400.

(2) Energy conversion efficiency (%) and fill factor (%):

Energy conversion efficiency (%) was measured using 1.5 AM 100 mW/cm² solar simulator (Xe lamp [300 W, Oriel], AM1.5 filter, and a Keithley SMU2400), and the fill factor was calculated using the energy conversion efficiency according to the following equation.

### Equation

Fill factor (FF)(%)={(J×V)ₘₐₓ/(J_{sc}×V_{oc})}×100

In the equation, J is a value of the y axis, Visa value of the x axis, and Jsc and Voc are respectively the y-intercept and x-intercept of a graph showing the energy conversion efficiency curve. In addition, current-voltage characteristics of the dye sensitized solar cells were analyzed using a Xe lamp (100 W/cm²) as a light source.

(3) The amount of dye adsorbed:

A titanium dioxide electrode was maintained at 80° C., and immersed in a dye dispersion prepared by dissolving N719 in ethanol to a concentration of 0.3 mM to adsorb the dye for 12 hours or more. Then, the dye immersed in the titanium dioxide electrode membrane was dissolved in a 1M NaOH solution, and UV-visible absorbance of the dye was measured to determine the amount of the dye adsorbed.

TABLE 1

| | | Oven | | | Amount |
|---|---|---|---|---|---|
| | Current | circuit | | | of dye |
| | density | voltage | Fill | | adsorbed |
| | (Jsc) | (Voc) | factor | Efficiency | (× 10⁻⁸ |
| | (mAcm⁻²) | (V) | (FF) | η(%) | molcm⁻²) |
| Example 1 | 16.2 | 0.76 | 69 | 8.62 | 5.384 |
| Compar- | 14.1 | 0.78 | 76 | 8.41 | 4.356 |
| ative | | | | | |
| Example 1 | | | | | |
| Compar- | 10.7 | 0.78 | 77 | 6.4 | 4.233 |
| ative | | | | | |
| Example 2 | | | | | |

Referring to Table 1, the dye sensitized solar cell according to Example 1 has a greater amount of dye adsorbed and higher efficiency than those of Comparative Examples 1 and 2.

As described above, the dye sensitized solar cell according to one or more of the above embodiments of the present invention has excellent efficiency due to high photocurrent density.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A photoelectrode for a dye sensitized solar cell, comprising:
mesoporous titanium dioxide particles having an average particle diameter in a range of about 100 to about 2000 nm and a specific surface area in a range of about 150 to about 300 m²/g; and
a photosensitive dye on a surface of the titanium dioxide particles.

2. The photoelectrode of claim 1, wherein mesopores of the mesoporous titanium dioxide particles have a distance between the mesopores in a range of about 4 to about 15 nm.

3. The photoelectrode of claim 1, wherein mesopores of the mesoporous titanium dioxide particles have an average pore diameter in a range of about 2 to about 7 nm and a pore volume in a range of about 0.03 to about 0.08 cc/g.

4. The photoelectrode of claim 1, wherein the mesoporous titanium dioxide particles exhibit at least one main diffraction peak at least one Bragg (20) angle in a range of about 0.8 to about 1.2 degrees, about 1.5 to about 3 degrees, or about 25 to about 30 degrees when CuK-alpha x-rays having a wavelength of 1.541 Å are irradiated thereto.

5. A method of manufacturing a photoelectrode for a dye sensitized solar cell, the method comprising:
preparing a composition for a photoelectrode by mixing mesoporous titanium dioxide particles, a polymer binder, an acid, and a solvent;
coating the composition for a photoelectrode on a substrate; and
heat treating the coated composition.

6. The method of claim 5, wherein the amount of the polymer binder is in a range of about 0.5 to about 50 parts by weight based on 100 parts by weight of the mesoporous titanium dioxide particles.

7. The method of claim 5, wherein the amount of the acid is in a range of about 50 to about 500 parts by weight based on 100 parts by weight of the mesoporous titanium dioxide particles.

8. The method of claim 5, wherein the heat treatment is performed at a temperature in a range of about 400 to about 550° C.

9. The method of claim 5, wherein the mesoporous titanium dioxide particles are prepared by:
preparing a titanium dioxide precursor mixture by mixing a titanium dioxide precursor, an acid, and a solvent;
impregnating mesoporous silica with the titanium dioxide precursor mixture and drying and heat treating the resultant; and
removing the mesoporous silica from the heat-treated resultant.

10. The method of claim 9, wherein the titanium dioxide precursor comprises a material selected from the group consisting of titanium ethoxide, titanium isopropoxide, titanium chloride, titanium methoxide, and combinations thereof.

11. The method of claim 9, wherein the amount of the acid in the titanium dioxide precursor mixture is in a range of about 30 to about 500 parts by weight based on 100 parts by weight of the mesoporous silica.

12. The method of claim 9, wherein the amount of the titanium dioxide precursor is in a range of about 50 to about 120 parts by weight based on 100 parts by weight of the mesoporous silica.

13. The method of claim 9, wherein the drying is performed at a temperature in a range of about 80 to about 160° C.

14. The method of claim 9, wherein the heat treatment is performed at a temperature in a range of about 400 to about 550° C.

15. The method of claim 9, wherein the mesoporous silica is removed using a sodium hydroxide (NaOH) solution.

16. A dye sensitized solar cell comprising:
a first electrode;
a photoelectrode according to claim 1 on one surface of the first electrode;
a second electrode facing the first electrode on which the photoelectrode is located; and
an electrolyte between the first electrode and the second electrode.

17. The dye sensitized solar cell of claim 16, further comprising a porous membrane having a metal oxide between the first electrode and the photoelectrode.

18. The dye sensitized solar cell of claim 17, wherein the metal oxide comprises a material selected from the group consisting of titanium dioxide, a zirconium oxide, a strontium oxide, a zinc oxide, a lanthanum oxide, a vanadium oxide, a molybdenum oxide, a tungsten oxide, a tin oxide, a niobium oxide, a magnesium oxide, an aluminum oxide, a yttrium oxide, a scandium oxide, a samarium oxide, a gallium oxide, a strontium titanium oxide, and combinations thereof.

19. The dye sensitized solar cell of claim 16, wherein mesopores of the mesoporous titanium dioxide particles have a distance between the mesopores in a range of about 4 to about 15 nm.

20. The dye sensitized solar cell of claim 16, wherein mesopores of the mesoporous titanium dioxide particles have an average pore diameter in a range of about 2 to about 7 nm and a pore volume in a range of about 0.03 to about 0.08 cc/g.
